(19) United States
(12) Patent Application Publication
(10) Pub. No.: US 2026/0177934 A1
(43) Pub. Date: Jun. 25, 2026

(54) STRUCTURE, EXPOSURE APPARATUS, AND ARTICLE MANUFACTURING METHOD

(71) Applicant: CANON KABUSHIKI KAISHA, Tokyo (JP)

(72) Inventors: SATORU OISHI, Tochigi (JP); SHIGEO KOYA, Tochigi (JP); TAKAHITO CHIBANA, Tochigi (JP)

(21) Appl. No.: 19/421,421

(22) Filed: Dec. 16, 2025

(30) Foreign Application Priority Data
Dec. 24, 2024 (JP) 2024-227963

(51) Int. Cl. G03F 7/00

(52) U.S. Cl. CPC G03F 7/70716; G03F 7/70833

(57) ABSTRACT

A structure includes a first plate, a second plate arranged to face the first plate, and a first connecting portion and a second connecting portion that connect the first plate and the second plate. The first plate includes a surface forming an upper surface of the structure. The second plate includes a surface forming a lower surface of the structure. On a section orthogonal to the upper surface and the lower surface, the first connecting portion and the second connecting portion have convex shapes in directions away from a barycenter of the structure.

### BACKGROUND

### Field of the Technology

The present disclosure relates to a structure, an exposure apparatus, and an article manufacturing method.

### Description of the Related Art

An exposure apparatus used to manufacture an article such as a semiconductor device or a liquid crystal display device can include a lens barrel surface plate that supports a projection optical system, and a top plate that supports a substrate chuck. The rigidities of structures such as a lens barrel surface plate and a top plate are related to the productivity and exposure accuracy of an exposure apparatus. Japanese Patent Laid-Open No. 11-142555 has described a technique in which a top plate has a hollow structure and a rib is provided in the hollow structure to increase the rigidity of the top plate.

To improve the productivity and exposure accuracy of the exposure apparatus, the eigenfrequency of the structure such as the lens barrel surface plate and/or the top plate is preferably increased. As a method of increasing the eigenfrequency of the structure, there are conceivable a method of increasing the rigidity of the structure, and a method of reducing the weight of the structure. As a method of increasing the rigidity, there are conceivable a method of thickening the structure, a method of increasing the sectional area of the structure, a method of increasing the number of reinforcing members, and the like. However, all these methods increase the weight of the structure and may hinder the improvement of the eigenfrequency.

### SUMMARY

The present disclosure provides a technique advantageous for increasing the eigenfrequency of a structure while suppressing an increase in the weight of the structure.

The present disclosure provides a structure comprising: a first plate; a second plate arranged to face the first plate; and a first connecting portion and a second connecting portion that connect the first plate and the second plate, wherein the first plate includes a surface forming an upper surface of the structure, the second plate includes a surface forming a lower surface of the structure, and on a section orthogonal to the upper surface and the lower surface, the first connecting portion and the second connecting portion have convex shapes in directions away from a barycenter of the structure.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIGS. 1A and 1B are schematic views showing the configuration of a structure according to the first embodiment;

FIGS. 2A and 2B are schematic views showing the configuration of a structure according to the second embodiment;

FIGS. 3A and 3B are schematic views showing the configuration of a structure according to the third embodiment;

FIGS. 4A and 4B are schematic views showing the configuration of a structure according to the fourth embodiment;

FIGS. 5A and 5B are schematic views showing the configuration of a structure according to the fifth embodiment;

FIGS. 6A and 6B are schematic views showing the configuration of a structure according to the sixth embodiment;

FIGS. 7A to 7C are schematic views showing the configuration of a structure according to the seventh embodiment;

FIGS. 8A to 8C are schematic views showing the configuration of a structure according to the eighth embodiment;

FIGS. 9A to 9C are schematic views showing the configuration of a structure according to the ninth embodiment;

FIGS. 10A to 10B are schematic views showing the configuration of a structure according to the 10th embodiment; and

FIG. 11 is a schematic view showing the configuration of an exposure apparatus according to the 11th embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In this specification and the accompanying drawings, directions are exemplified in an XYZ coordinate system. The X-axis, the Y-axis, and the X-Y plane are parallel to the horizontal plane, and the direction of the Z-axis is parallel to the vertical direction.

In this specification and appended claims, an expression “connecting the first member (for example, the first plate) and the second member (for example, the second plate) by a connecting portion” or similar expressions should be interpreted in the broadest sense. This expression includes connecting each member and a connecting portion by means of bolting, welding, adhesion, joining, or the like to integrate the two or more members and the connecting portion. This expression also includes integrally molding the two or more members and the connecting portion. That is, this expression can be used to simply specify a shape. For example, even an integrally molded structure can be expressed as a structure having a shape formed by connecting two or more members of arbitrary shapes by a connecting portion, in order to specify the shape of the structure.

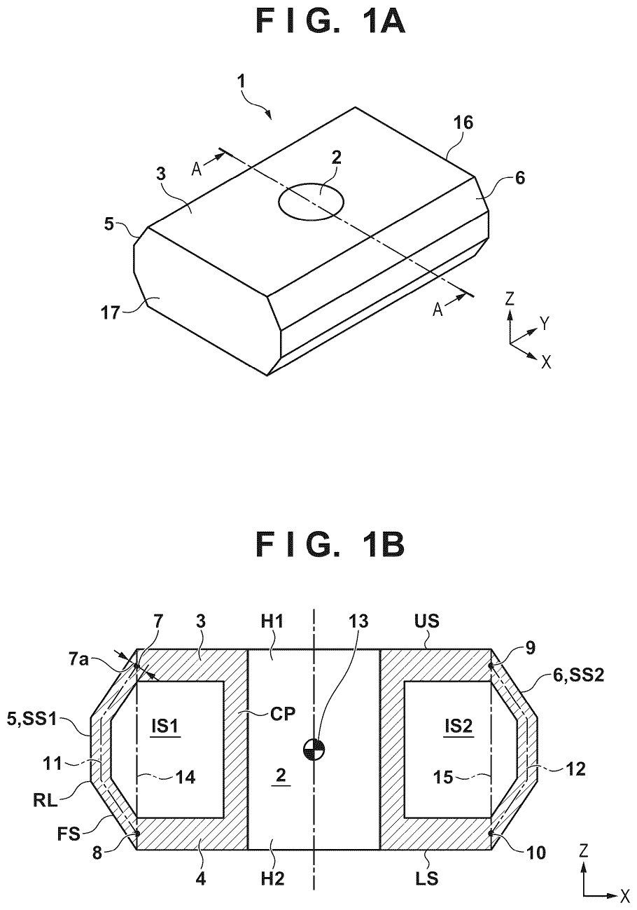

FIGS. 1A and 1B are schematic views showing a structure 1 according to the first embodiment. FIG. 1A is an oblique view from above, and FIG. 1B is a sectional view taken along a line A-A in FIG. 1A. FIG. 1B is a sectional view passing through the barycenter of the structure 1. The structure 1 can be formed as, for example, the surface plate of an exposure apparatus. The structure 1 can include a first plate 3, and a second plate 4 arranged to face the first plate 3. The first plate 3 can have a surface forming an upper surface US of the structure 1. The second plate 4 can have a surface forming a lower surface LS of the structure 1. The structure 1 can also include a first connecting portion 5 and a second connecting portion 6 that connect the first plate 3 and the second plate 4. The structure 1 can also include a connecting portion 16 and a connecting portion 17 that connect the first plate 3 and the second plate 4.

FIG. 1B shows a section orthogonal to the upper surface US and the lower surface LS. On the section orthogonal to the upper surface US and the lower surface LS, the first connecting portion 5 and the second connecting portion 6 can have convex shapes in directions away from a barycenter 13 of the structure 1. From another viewpoint, FIG. 1B shows a section passing through the barycenter 13 of the structure 1 and orthogonal to the upper surface US and the lower surface LS. On the section passing through the barycenter 13 of the structure 1 and orthogonal to the upper surface US and the lower surface LS, the first connecting portion 5 and the second connecting portion 6 can have convex shapes in the directions away from the barycenter 13 of the structure 1. The upper surface US and lower surface LS of the structure 1 may be parallel to the horizontal plane. On the section passing through the barycenter 13 of the structure 1 and orthogonal to the upper surface US and the lower surface LS, the first connecting portion 5 and the second connecting portion 6 can have convex shapes from the barycenter 13 in the horizontal direction. The first connecting portion 5 can be arranged so that a first internal space IS1 partially defined by the first plate 3, the second plate 4, and the first connecting portion 5 is provided in the structure 1. The second connecting portion 6 can be arranged so that a second internal space IS2 partially defined by the first plate 3, the second plate 4, and the second connecting portion 6 is provided in the structure 1.

The structure 1 has a through hole 2 passing through the first plate 3 and the second plate 4, and the barycenter 13 of the structure 1 can be positioned in the through hole 2. The first plate 3 can have a first through hole H1, and the second plate 4 can have a second through hole H2. The structure 1 can have a cylindrical portion CP that connects the first plate 3 and the second plate 4. The inner surface of the cylindrical portion CP, the first through hole H1, and the second through hole H2 can form one cylindrical surface.

The first connecting portion 5 can have a surface forming a first side surface SS1 of the structure 1, and the second connecting portion 6 can have a surface forming a second side surface SS2 of the structure 1. On the section orthogonal to the upper surface US and lower surface LS of the structure 1, the first side surface SS1 and the second side surface SS2 can have convex shapes in the directions away from the barycenter 13 of the structure 1. Each of the first side surface SS1 and the second side surface SS2 can have a ridge line RL and a flat surface FS. In the example shown in FIGS. 1A and 1B, each of the first side surface SS1 and the second side surface SS2 can have two ridge lines RL and three flat surfaces FS.

In one aspect, a center line 11 as an aggregate of center points of the first connecting portion 5 in the direction of thickness may be spaced more apart from the barycenter 13 of the structure 1 than a virtual line 14 connecting a center 7 of the boundary between the first connecting portion 5 and the first plate 3 and a center 8 of the boundary between the first connecting portion 5 and the second plate 4. That is, the first connecting portion 5 may have a convex shape in the direction away from the barycenter 13 of the structure 1. Similarly, a center line 12 as an aggregate of center points of the second connecting portion 6 in the direction of thickness may be spaced more apart from the barycenter 13 of the structure 1 than a virtual line 15 connecting a center 9 of the boundary between the second connecting portion 6 and the first plate 3 and a center 10 of the boundary between the second connecting portion 6 and the second plate 4. That is, the first connecting portion 5 and the second connecting portion 6 may have convex shapes in the directions away from the barycenter 13 of the structure 1. Note that the connecting portions 16 and 17 can have flat shapes. The first plate 3, the second plate 4, the first connecting portion 5, and the second connecting portion 6 may be individually prepared and then connected to each other, or integrally molded by casting or the like. In the case of casting, the above-mentioned boundaries are not physical planes but virtual planes.

The first connecting portion 5 and the second connecting portion 6 can have three-dimensional shapes. The first side surface SS1 of the first connecting portion 5 and the second side surface SS2 of the second connecting portion 6 can also have three-dimensional shapes. The center line 11, the center line 12, the virtual line 14, and the virtual line 15 may be common at a plurality of positions in the Y direction. In addition to the section A-A shown in FIG. 1A, there are various sections passing through the barycenter 13 and orthogonal to the upper surface US and the lower surface LS. On these sections, the first connecting portion 5 and the second connecting portion 6 can have convex shapes from the barycenter 13 in the horizontal direction.

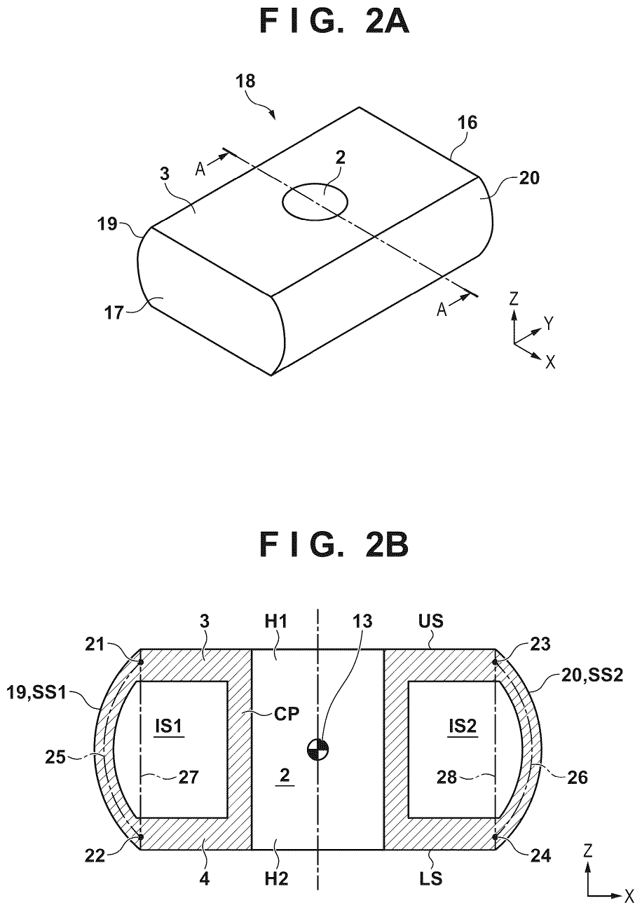

Since the first connecting portion 5 and the second connecting portion 6 have convex shapes in the directions away from the barycenter 13 of the structure 1, the eigenfrequency of the structure 1 can be increased while suppressing an increase in the weight of the structure 1. Table 1 shows the effect of the connecting portion having a convex shape in the direction away from the barycenter 13 of the structure 1. Table 1 shows the ratios of the weight and eigenfrequency of the structure 1 in the first embodiment shown in FIGS. 1A and 1B in a case where the weight and eigenfrequency of a comparative example in which a connecting portion does not have a convex shape are defined as 1. Table 1 also shows the effects of the second, third, and fourth embodiments shown in FIGS. 2A and 2B, FIGS. 3A and 3B, and FIGS. 4A and 4B to be described later.

TABLE 1

| | Compar- | First | Second | Third | Fourth |
|---|---|---|---|---|---|
| | ative | Embodi- | Embodi- | Embodi- | Embodi- |
| | Example | ment | ment | ment | ment |
| Weight | 1 | 0.907 | 0.91 | 0.89 | 1.03 |
| (ratio) | | | | | |
| Eigen- | 1 | 1.07 | 1.05 | 1.04 | 1.46 |
| frequency | | | | | |
| (ratio) | | | | | |

As shown in Table 1, in the structure 1 according to the first embodiment (FIGS. 1A and 1B) in which the connecting portions 5 and 6 have convex shapes in the directions away from the barycenter 13 of the structure 1, the eigenfrequency of the structure 1 can be increased while suppressing an increase in the weight of the structure 1, compared to the comparative example.

To effectively increase the eigenfrequency, at least part of each of the center lines 11 and 12 is preferably arranged at a position having a distance of 5% or more of the thickness of the connecting portion 5 or 6 in the direction away from the barycenter 13 of the structure 1. That is, each of the connecting portions 5 and 6 preferably has a swelling of 5% or more of the thickness of the connecting portion 5 or 6 in the direction away from the barycenter 13 of the structure 1. Here, the thickness of the first connecting portion 5 is 7a in FIG. 1B. Note that when the thicknesses of the connecting portions 5 and 6 are different, the connecting portions 5 and 6 preferably have a swelling of 5% or more of the thickness of the thinner connecting portion.

The structure 1 formed as the surface plate of the exposure apparatus can be supported by, for example, an antivibration mount. In this case, a support surface supported by the antivibration mount can be provided on the second plate 4 of the structure 1. For example, a pneumatic actuator can be built in the antivibration mount to actively control the position of the structure 1 serving as a surface plate. Note that, other than the pneumatic actuator, a linear motor may be used as the actuator, or both of them may be used. Such an application example is also applicable to various embodiments to be described later. When a projection optical system is supported by the structure 1 formed as the surface plate, a support portion that supports the projection optical system is provided on the structure 1. In one example, the position of the structure 1 formed as the surface plate is controlled. In another example, vibrations of the structure 1 formed as the surface plate are controlled. When vibrations of the structure 1 are controlled, the structure 1 can be supported via an elastic member such as an antivibration rubber or an air spring. As a matter of course, it is also possible to detect vibrations in real time and actively control them based on the information. Such an application example is also applicable to various embodiments to be described later.

The structure 1 can be formed from, for example, a low-thermal-expansion material, a stainless material, a steel material, or an aluminum material. The structure 1 can be formed as a cast by casting. Alternatively, the structure 1 may be manufactured by assembling a plurality of members by welding or the like. Alternatively, the structure 1 may be manufactured by a 3D printer. Manufacturing the structure 1 by a 3D printer advantageously increases the degree of freedom of the shape of the structure 1. Note that in the example of FIGS. 1A and 1B, the first connecting portion 5 and second connecting portion 6 of the structure 1 are formed by linear portions. Such a shape facilitates manufacturing the structure 1 by casting or welding.

When the through hole 2 is provided in the structure 1, as described above, the projection optical system can be inserted into the through hole 2 and supported by the first plate 3. The projection optical system can be fastened by, for example, a bolt to the first plate 3. The inner surface of the cylindrical portion CP can be formed not to contact the projection optical system. When the structure 1 is not formed as a surface plate (lens barrel surface plate) that supports the projection optical system, the through hole 2 may not be necessary. Whether to provide the through hole 2, and the shape and dimensions of the through hole 2 can be determined in accordance with the application purpose of the structure 1.

The second embodiment will be explained below. Matters which will not be mentioned as the second embodiment may or may not be pursuant to the first embodiment. FIGS. 2A and 2B are schematic views showing a structure 18 according to the second embodiment. FIG. 2A is an oblique view from above, and FIG. 2B is a sectional view taken along a line A-A in FIG. 2A. The structure 18 can be formed as, for example, the surface plate of an exposure apparatus. The structure 18 can include a first plate 3, and a second plate 4 arranged to face the first plate 3. The first plate 3 can have a surface forming an upper surface US of the structure 18. The second plate 4 can have a surface forming a lower surface LS of the structure 18. The structure 18 can also include a first connecting portion 19 and a second connecting portion 20 that connect the first plate 3 and the second plate 4. The structure 18 can also include a connecting portion 16 and a connecting portion 17 that connect the first plate 3 and the second plate 4.

FIG. 2B shows a section orthogonal to the upper surface US and the lower surface LS. On the section orthogonal to the upper surface US and the lower surface LS, the first connecting portion 19 and the second connecting portion 20 can have convex shapes in directions away from a barycenter 13 of the structure 18. From another viewpoint, FIG. 2B shows a section passing through the barycenter 13 of the structure 18 and orthogonal to the upper surface US and the lower surface LS. On the section passing through the barycenter 13 of the structure 18 and orthogonal to the upper surface US and the lower surface LS, the first connecting portion 19 and the second connecting portion 20 can have convex shapes in the directions away from the barycenter 13 of the structure 18. The upper surface US and lower surface LS of the structure 18 may be parallel to the horizontal plane. On the section passing through the barycenter 13 of the structure 18 and orthogonal to the upper surface US and the lower surface LS, the first connecting portion 19 and the second connecting portion 20 can have convex shapes from the barycenter 13 in the horizontal direction. The first connecting portion 19 can be arranged so that a first internal space IS1 partially defined by the first plate 3, the second plate 4, and the first connecting portion 19 is provided in the structure 18. The second connecting portion 20 can be arranged so that a second internal space IS2 partially defined by the first plate 3, the second plate 4, and the second connecting portion 20 is provided in the structure 18.

The structure 18 has a through hole 2 passing through the first plate 3 and the second plate 4, and the barycenter 13 of the structure 18 can be positioned in the through hole 2. The first plate 3 can have a first through hole H1, and the second plate 4 can have a second through hole H2. The structure 18 can have a cylindrical portion CP that connects the first plate 3 and the second plate 4. The inner surface of the cylindrical portion CP, the first through hole H1, and the second through hole H2 can form one cylindrical surface.

The first connecting portion 19 can have a surface forming a first side surface SS1 of the structure 18, and the second connecting portion 20 can have a surface forming a second side surface SS2 of the structure 18. On the section orthogonal to the upper surface US and lower surface LS of the structure 18, the first side surface SS1 and the second side surface SS2 can have convex shapes in the directions away from the barycenter 13 of the structure 18. In the example shown in FIGS. 2A and 2B, each of the first side surface SS1 and the second side surface SS2 can have a curved surface. The generating line of the curved surface may be parallel to the upper surface US and the lower surface LS.

A center line 25 as an aggregate of center points of the first connecting portion 19 in the direction of thickness may be spaced more apart from the barycenter 13 of the structure 18 than a virtual line 27 connecting a center 21 of the boundary between the first connecting portion 19 and the first plate 3 and a center 22 of the boundary between the first connecting portion 19 and the second plate 4. That is, the first connecting portion 19 may have a convex shape in the direction away from the barycenter 13 of the structure 18. Similarly, a center line 26 as an aggregate of center points of the second connecting portion 20 in the direction of thickness may be spaced more apart from the barycenter 13 of the structure 18 than a virtual line 28 connecting a center 23 of the boundary between the second connecting portion 20 and the first plate 3 and a center 24 of the boundary between the second connecting portion 20 and the second plate 4.

By forming the first connecting portion 19 and the second connecting portion 20 to have convex shapes in the directions away from the barycenter 13 of the structure 18, the eigenfrequency of the structure 18 can be increased while suppressing an increase in the weight of the structure 18, as shown in Table 1. The structure 18 having the first connecting portion 19 and the second connecting portion 20 with curved shapes can be formed using, for example, a 3D printer.

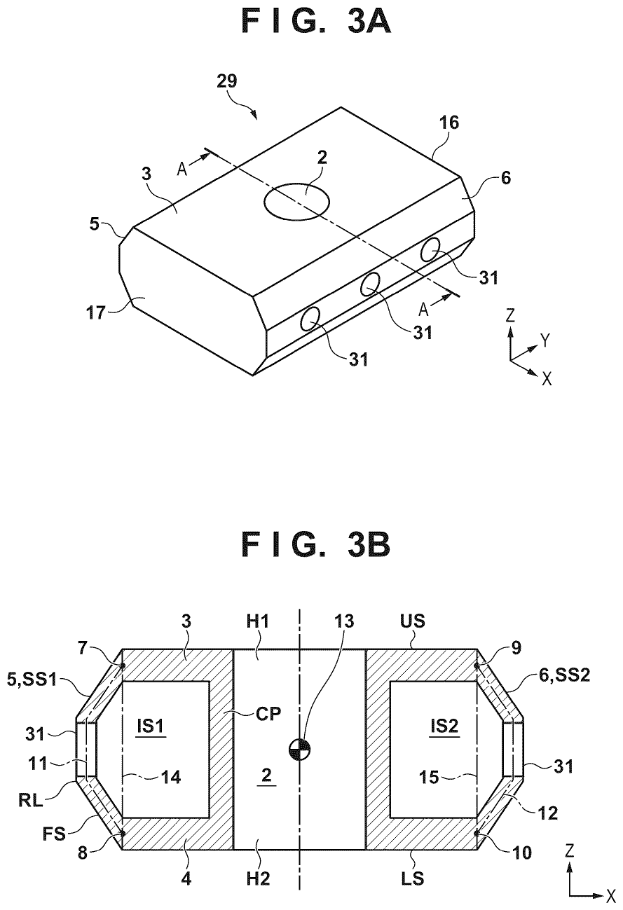

The third embodiment will be explained below. Matters which will not be mentioned as the third embodiment may or may not be pursuant to the first embodiment. FIGS. 3A and 3B are schematic views showing a structure 29 according to the third embodiment. FIG. 3A is an oblique view from above, and FIG. 3B is a sectional view taken along a line A-A in FIG. 3A. In the structure 29 according to the third embodiment, holes 31 are provided in a first connecting portion 5 and a second connecting portion 6. Also in the third embodiment, the first connecting portion 5 and the second connecting portion 6 can have convex shapes in directions away from a barycenter 13 of the structure 29. Thus, the eigenfrequency of the structure 29 can be increased while suppressing an increase in the weight of the structure 29, compared to the comparative example. In addition, the structure 29 according to the third embodiment is superior in weight reduction to the structure 1 according to the first embodiment because the holes 31 are provided in the first connecting portion 5 and the second connecting portion 6. Although the holes 31 are provided in the first connecting portion 5 and the second connecting portion 6 in the configuration shown in FIGS. 3A and 3B, the holes 31 may be provided in at least either of the first connecting portion 5 and the second connecting portion 6. Further, holes may be provided in at least either of a first plate 3 and a second plate 4. From another viewpoint, holes may be provided in at least one of the first connecting portion 5, the second connecting portion, the first plate 3, and the second plate 4. Also in the structure 18 according to the second embodiment described above, holes may be provided in at least one of the first connecting portion 19, the second connecting portion 20, the first plate 3, and the second plate 4.

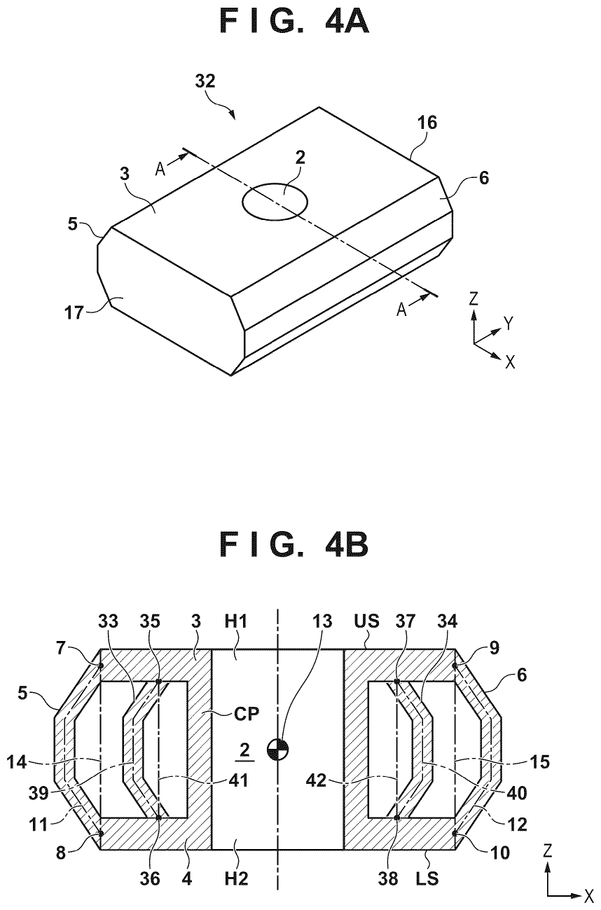

The fourth embodiment will be explained below. Matters which will not be mentioned as the fourth embodiment may or may not be pursuant to at least one of the first to third embodiments. FIGS. 4A and 4B are schematic views showing a structure 32 according to the fourth embodiment. FIG. 4A is an oblique view from above, and FIG. 4B is a sectional view taken along a line A-A in FIG. 4A.

Similar to the structure 1 according to the first embodiment, the structure 32 according to the fourth embodiment can include a first plate 3, a second plate 4 arranged to face the first plate 3, and a first connecting portion 5 and a second connecting portion 6 that connect the first plate 3 and the second plate 4. The structure 32 can also include a connecting portion 16 and a connecting portion 17 that connect the first plate 3 and the second plate 4. In addition, the structure 32 can include a third connecting portion 33 and a fourth connecting portion 34 that connect the first plate 3 and the second plate 4. The third connecting portion 33 can be arranged between the first connecting portion 5 and a barycenter 13 of the structure 32. The fourth connecting portion 34 can be arranged between the second connecting portion 6 and the barycenter 13. On a section orthogonal to an upper surface US and a lower surface LS, the third connecting portion 33 and the fourth connecting portion 34 can have convex shapes in directions away from the barycenter 13 of the structure 32.

The first plate 3 can have a first through hole H1, and the second plate 4 can have a second through hole H2. The structure 32 can have a cylindrical portion CP that connects the first plate 3 and the second plate 4. The inner surface of the cylindrical portion CP, the first through hole H1, and the second through hole H2 can form one cylindrical surface. The cylindrical portion CP can be arranged between the third connecting portion 33 and the fourth connecting portion 34. A center line 39 as an aggregate of center points of the third connecting portion 33 in the direction of thickness may be spaced more apart from the barycenter 13 of the structure 32 than a virtual line 41 connecting a center 35 of the boundary between the third connecting portion 33 and the first plate 3 and a center 36 of the boundary between the third connecting portion 33 and the second plate 4. That is, the third connecting portion 33 may have a convex shape in the direction away from the barycenter 13 of the structure 32. Similarly, a center line 40 as an aggregate of center points of the fourth connecting portion 34 in the direction of thickness may be spaced more apart from the barycenter 13 of the structure 32 than a virtual line 42 connecting a center 37 of the boundary between the fourth connecting portion 34 and the first plate 3 and a center 38 of the boundary between the fourth connecting portion 34 and the second plate 4. That is, the first connecting portion 5, the second connecting portion 6, the third connecting portion 33, and the fourth connecting portion 34 may have convex shapes in the directions away from the barycenter 13 of the structure 32.

Since the convex connecting portions are formed in two lines in the fourth embodiment, the eigenfrequency of the structure 32 can be increased while suppressing an increase in the weight of the structure 32, as shown in Table 1. Note that convex connecting portions may be formed in three or more lines, which can further increase the eigenfrequency. An optimum number and arrangement of connecting portions can be freely determined in accordance with the difficulty of manufacture, the weight of a surface plate, rigidity, and the like.

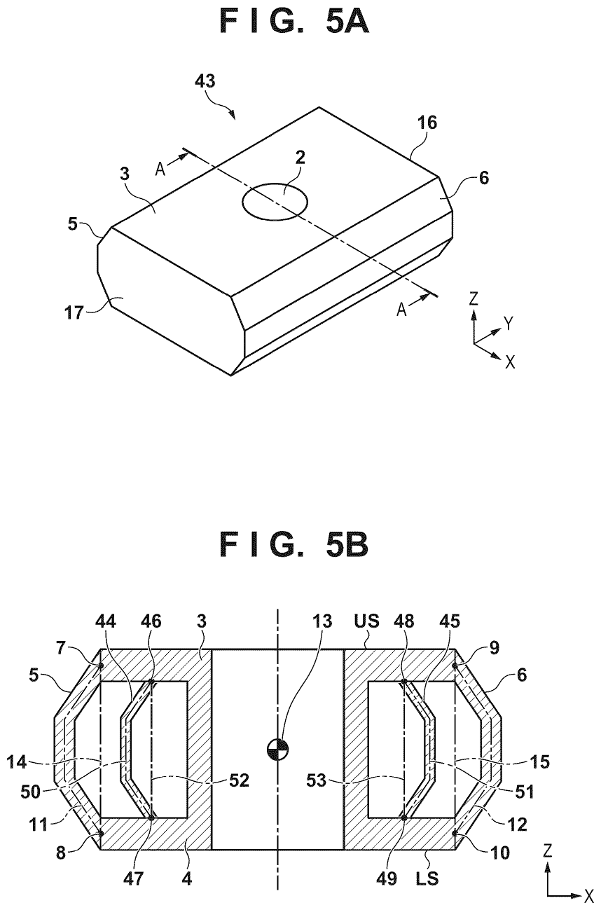

The fifth embodiment will be explained below. Matters which will not be mentioned as the fifth embodiment may or may not be pursuant to the fourth embodiment. FIGS. 5A and 5B are schematic views showing a structure 43 according to the fifth embodiment. FIG. 5A is an oblique view from above, and FIG. 5B is a sectional view taken along a line A-A in FIG. 5A. In the fifth embodiment, the thicknesses of a third connecting portion 44 and a fourth connecting portion 45 are smaller than those of a first connecting portion 5 and a second connecting portion 6. A center line 50 as an aggregate of center points of the third connecting portion 44 in the direction of thickness may be spaced more apart from a barycenter 13 of the structure 43 than a virtual line 52 connecting a center 46 of the boundary between a first plate 3 and the third connecting portion 44 and a center 47 of the boundary between a second plate 4 and the third connecting portion 44. A center line 51 as an aggregate of center points of the fourth connecting portion 45 in the direction of thickness may be spaced more apart from the barycenter 13 of the structure 43 than a virtual line 53 connecting a center 48 of the boundary between the first plate 3 and the fourth connecting portion 45 and a center 49 of the boundary between the second plate 4 and the fourth connecting portion 45. Similar to the first connecting portion 5 and the second connecting portion 6, the third connecting portion 44 and the fourth connecting portion 45 may have convex shapes in directions away from the barycenter 13 of the structure 43.

According to the fifth embodiment, the eigenfrequency of the structure 43 can be increased while suppressing an increase in the weight of the structure 43. Also, according to the fifth embodiment, the weight of the structure 43 can be reduced because the thicknesses of the third connecting portion 44 and fourth connecting portion 45 are smaller than those of the first connecting portion 5 and second connecting portion 6.

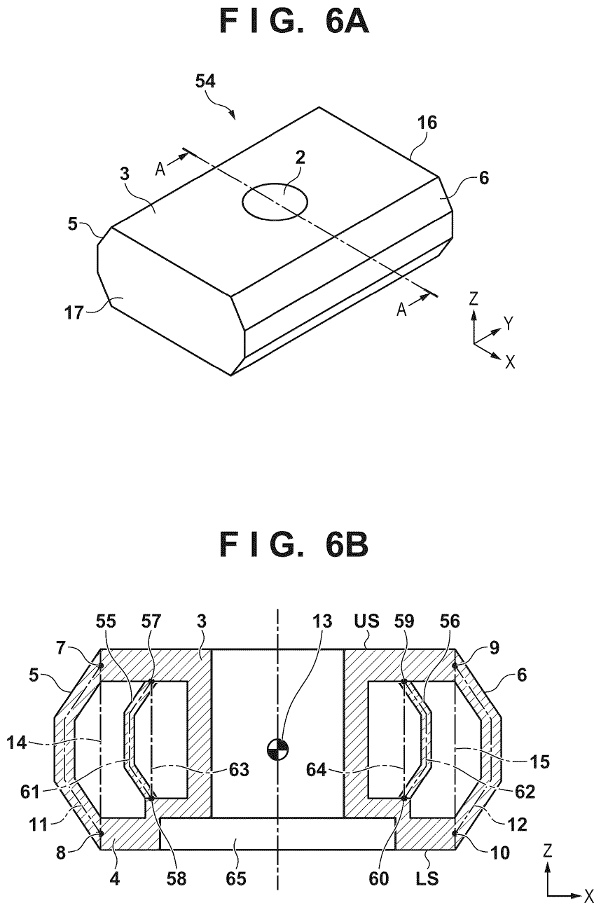

The sixth embodiment will be explained below. Matters which will not be mentioned as the sixth embodiment may or may not be pursuant to the fifth embodiment. FIGS. 6A and 6B are schematic views showing a structure 54 according to the sixth embodiment. FIG. 6A is an oblique view from above, and FIG. 6B is a sectional view taken along a line A-A in FIG. 6A. In the structure 54 according to the sixth embodiment, a recess (counterbore) 65 is provided in a second plate 4. When the structure 54 is used as the surface plate of an exposure apparatus, the recess 65 is advantageous for arranging the structure 54 in a restricted space. This is advantageous for downsizing the exposure apparatus.

The structure 54 can include a first plate 3, a second plate 4 arranged to face the first plate 3, and a first connecting portion 5 and a second connecting portion 6 that connect the first plate 3 and the second plate 4. The structure 54 can also include a connecting portion 16 and a connecting portion 17 that connect the first plate 3 and the second plate 4. Further, the structure 54 can include a third connecting portion 55 and a fourth connecting portion 56 that connect the first plate 3 and the second plate 4. The third connecting portion 55 can be arranged between the first connecting portion 5 and a barycenter 13 of the structure 54. The fourth connecting portion 56 can be arranged between the second connecting portion 6 and the barycenter 13. On a section orthogonal to an upper surface US and a lower surface LS, the third connecting portion 55 and the fourth connecting portion 56 can have convex shapes in directions away from the barycenter 13 of the structure 54. In a direction (Z direction) orthogonal to the upper surface US and the lower surface LS, the dimensions of the third connecting portion 55 and fourth connecting portion 56 may be smaller than those of the first connecting portion 5 and second connecting portion 6.

A center line 61 as an aggregate of center points of the third connecting portion 55 in the direction of thickness may be spaced more apart from the barycenter 13 of the structure 54 than a virtual line 63 connecting a center 57 of the boundary between the first plate 3 and the third connecting portion 55 and a center 58 of the boundary between the second plate 4 and the third connecting portion 55. A center line 62 as an aggregate of center points of the fourth connecting portion 56 in the direction of thickness may be spaced more apart from the barycenter 13 of the structure 54 than a virtual line 64 connecting a center 59 of the boundary between the first plate 3 and the fourth connecting portion 56 and a center 60 of the boundary between the second plate 4 and the fourth connecting portion 56. Similar to the first connecting portion 5 and the second connecting portion 6, the third connecting portion 55 and the fourth connecting portion 56 may have convex shapes in the directions away from the barycenter 13 of the structure 54.

Since the connecting portions 5, 6, 55, and 56 have convex shapes in the directions away from the barycenter 13 of the structure 54 also in the sixth embodiment, the eigenfrequency of the structure 54 can be increased while suppressing an increase in the weight of the structure 54.

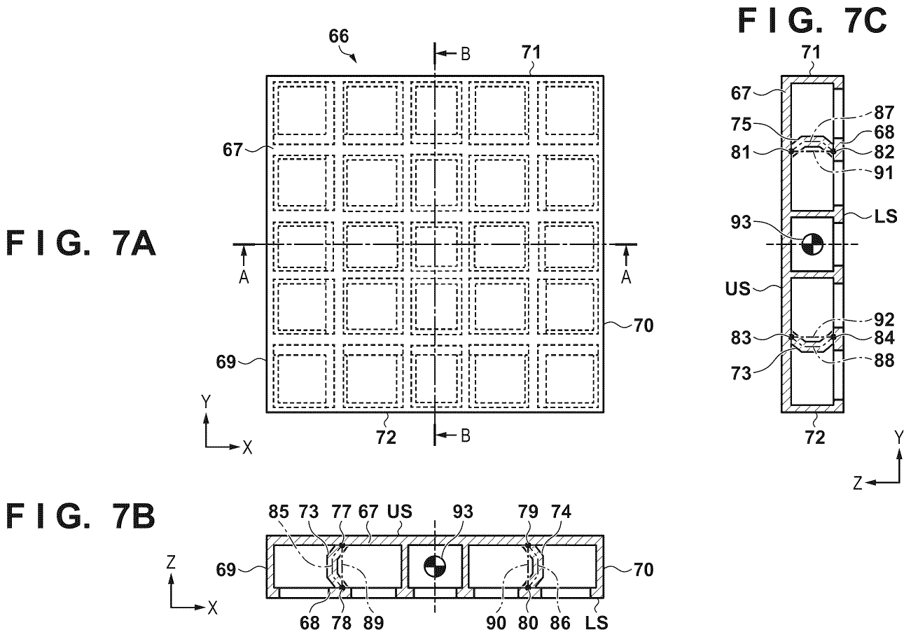

The seventh embodiment will be explained below. Matters which will not be mentioned as the seventh embodiment may or may not be pursuant to at least one of the first to sixth embodiments. FIGS. 7A to 7C are schematic views showing a structure 66 according to the seventh embodiment. FIG. 7A is a view of the structure 66 when viewed from directly above, and FIGS. 7B and 7C are sectional views taken along a line A-A and a line B-B in FIG. 7A, respectively. In the seventh embodiment, connecting portions 73 and 74 having convex shapes in directions away from a barycenter 93 of the structure 66 are arranged inside the structure 66. The structure 66 can be formed as, for example, a top plate that supports a substrate chuck.

The structure 66 can include a first plate 67, and a second plate 68 arranged to face the first plate 67. The first plate 67 can have a surface forming an upper surface US of the structure 66. The second plate 68 can have a surface forming a lower surface LS of the structure 66. The structure 66 can also include the connecting portion 73, the connecting portion 74, a connecting portion 75, and a connecting portion 76 that connect the first plate 67 and the second plate 68. The structure 66 can also include connecting portions 69, 70, 71, and 72 that connect the first plate 67 and the second plate 68. The connecting portions 69, 70, 71, and 72 can have flat shapes. On a section orthogonal to the upper surface US and the lower surface LS, the connecting portions 73, 74, 75, and 76 can have convex shapes in the directions away from the barycenter 93 of the structure 66. Since the connecting portions 73, 74, 75, and 76 have convex shapes in the directions away from the barycenter 93 of the structure 66, the eigenfrequency of the structure 66 can be increased while suppressing an increase in the weight of the structure 66.

A center line 85 as an aggregate of center points of the connecting portion 73 in the direction of thickness may be spaced more apart from the barycenter 93 of the structure 66 than a virtual line 89 connecting a center 77 of the boundary between the first plate 67 and the connecting portion 73 and a center 78 of the boundary between the second plate 68 and the connecting portion 73. A center line 86 as an aggregate of center points of the connecting portion 74 in the direction of thickness may be spaced more apart from the barycenter 93 of the structure 66 than a virtual line 90 connecting a center 79 of the boundary between the first plate 67 and the connecting portion 74 and a center 80 of the boundary between the second plate 68 and the connecting portion 74. A center line 87 as an aggregate of center points of the connecting portion 75 in the direction of thickness may be spaced more apart from the barycenter 93 of the structure 66 than a virtual line 91 connecting a center 81 of the boundary between the first plate 67 and the connecting portion 75 and a center 82 of the boundary between the second plate 68 and the connecting portion 75. A center line 88 as an aggregate of center points of the connecting portion 76 in the direction of thickness may be spaced more apart from the barycenter 93 of the structure 66 than a virtual line 92 connecting a center 83 of the boundary between the first plate 67 and the connecting portion 76 and a center 84 of the boundary between the second plate 68 and the connecting portion 76.

In one example, openings are formed in the second plate 68, and such a configuration is advantageous for reducing the weight of the structure 66. Instead of forming openings, however, the structure 66 may be a hollow structure. The side surface of the structure 66 need not always be continuous, and a notch may be partially formed. The shape of the side surface of the structure 66 can be freely determined. The eigenfrequency of the structure 66 can be increased by constituting the connecting portions 73, 74, 75, and 76 regardless of the shape of the side surface of the structure 66.

When the structure 66 is constituted as the top plate of an exposure apparatus, for example, as a top plate that supports a substrate chuck, the position, speed, acceleration, or the like of the structure 66 can be feedback-controlled using a measurement device such as a laser interferometer or an encoder. The structure 66 can be formed from, for example, ceramics, a low-expansion material, a stainless material, a steel material, or an aluminum material. The structure 66 is preferably formed from ceramics to suppress the weight of the structure 66.

The structure 66 formed as a top plate can have a flat side surface. Such a configuration is advantageous for providing a mirror on the side surface of the structure 66 when measuring the position of the structure 66 by a laser interferometer, and also for improving the degree of freedom of arranging other constituent components around the structure 66. When there is no restriction on the side surface of the structure 66, the side surface of the structure 66 may have a convex shape as in the above-described embodiments.

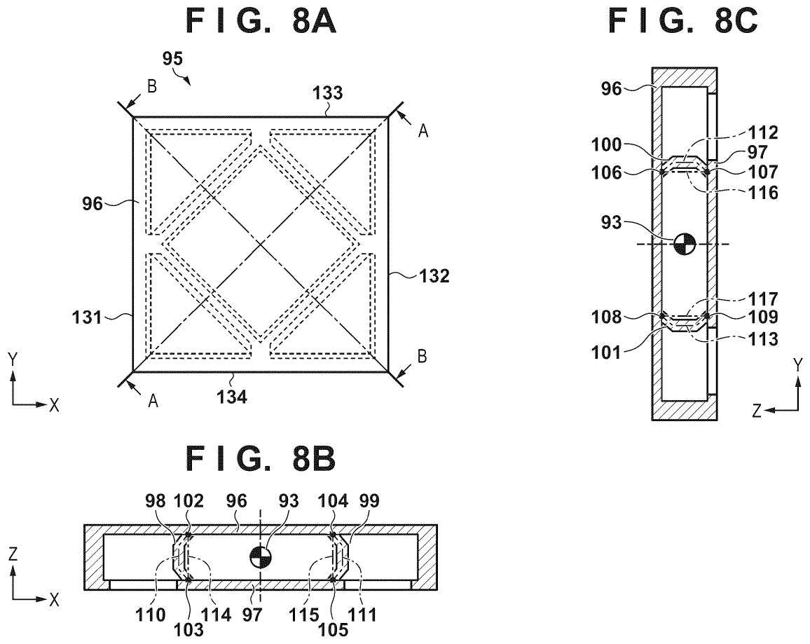

The eighth embodiment will be explained below. Matters which will not be mentioned as the eighth embodiment may or may not be pursuant to the seventh embodiment. FIGS. 8A to 8C are schematic views showing a structure 95 according to the eighth embodiment. FIG. 8A is a view of the structure 95 when viewed from directly above, and FIGS. 8B and 8C are sectional views taken along a line A-A and a line B-B in FIG. 8A, respectively. In the structure 95 of the eighth embodiment, connecting portions 98, 99, 100, and 101 each having a convex shape are arranged inside the structure 95. In the structure 95, the connecting portions 98, 99, 100, and 101 can be connected at angles to connecting portions 131, 132, 133, and 134 forming side surfaces of the structure 95. The structure 95 can be formed as, for example, a top plate that supports a substrate chuck.

As for the connecting portions 98, 99, 100, and 101, center lines, the centers of boundaries, and virtual lines are defined similarly to those in the above-described embodiments. Reference numerals 110, 111, 112, and 113 denote center lines each as an aggregate of center points in the direction of thickness. Reference numerals 102, 104, 106, and 108 denote centers of the boundaries between the connecting portions 98, 99, 100, and 101 and a first plate 96; and 103, 105, 107, and 109, centers of the boundaries between the connecting portions 98, 99, 100, and 101 and a second plate 97. Reference numerals 114, 115, 116, and 117 denote virtual lines. The center lines 110, 111, 112, and 113 can be arranged at positions more apart from a barycenter 93 than the virtual lines 114, 115, 116, and 117. That is, the connecting portions 98, 99, 100, and 101 have convex shapes in directions away from the barycenter 93 of the structure 95. By providing the connecting portions having convex shapes in the directions away from the barycenter of the structure, as exemplified as the eighth embodiment, the eigenfrequency of the structure can be increased while suppressing an increase in the weight of the structure.

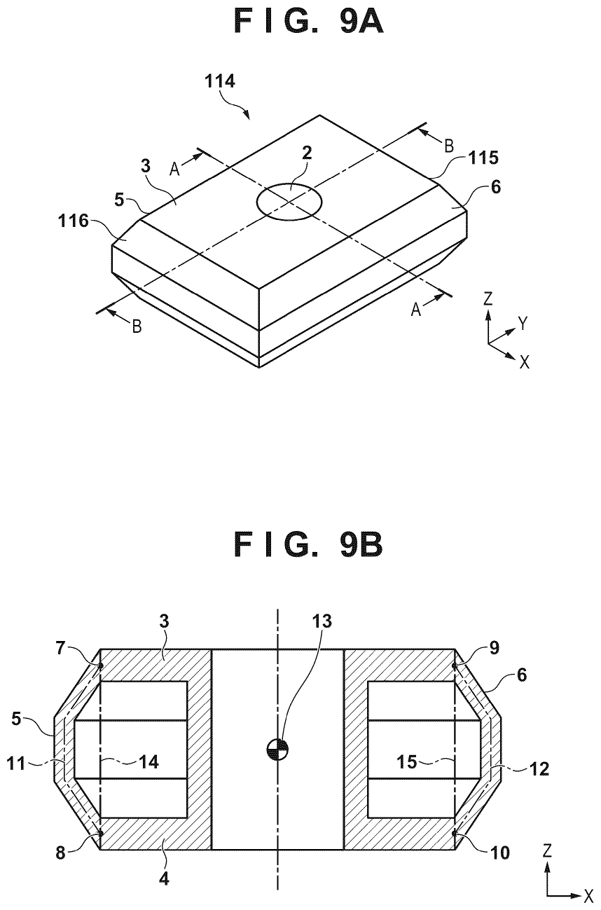

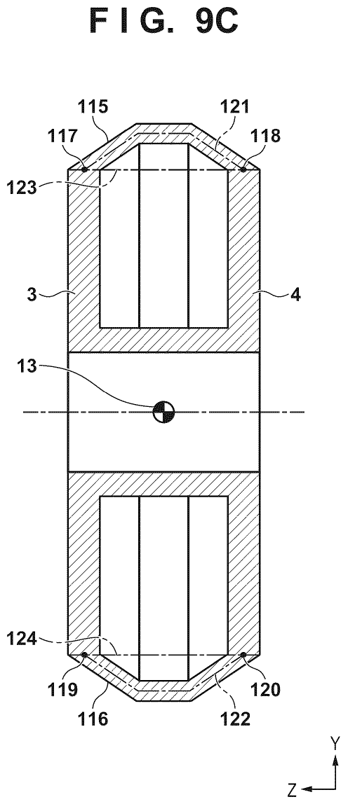

The ninth embodiment will be explained below. Matters which will not be mentioned as the ninth embodiment may or may not be pursuant to at least one of the first to eighth embodiments. FIGS. 9A to 9C are schematic views showing a structure 114 according to the ninth embodiment. FIG. 9A is a view of the structure 114 when viewed from directly above, and FIGS. 9B and 9C are sectional views taken along a line A-A and a line B-B in FIG. 9A, respectively.

In one aspect of the ninth embodiment, each of connecting portions 5, 6, 115, and 116 forming four side surfaces of the structure 114 has a convex shape in a direction away from a barycenter 13 of the structure 114. A center line 121 as an aggregate of center points of the connecting portion 115 in the direction of thickness may be spaced more apart from the barycenter 13 of the structure 114 than a virtual line 123 connecting a center 117 of the boundary between the connecting portion 115 and the first plate 3 and a center 118 of the boundary between the connecting portion 115 and the second plate 4. A center line 122 as an aggregate of center points of the connecting portion 116 in the direction of thickness may be spaced more apart from the barycenter 13 of the structure 114 than a virtual line 124 connecting a center 119 of the boundary between the connecting portion 116 and the first plate 3 and a center 120 of the boundary between the connecting portion 116 and the second plate 4. That is, the connecting portions 5, 6, 115, and 116 have convex shapes in the directions away from the barycenter 13 of the structure 114.

The configuration in which each of the connecting portions 5, 6, 115, and 116 forming four side surfaces of the structure 114 has a convex shape in the direction away from the barycenter 13 of the structure 114 is advantageous for increasing the eigenfrequency of the structure 114 while suppressing an increase in the weight of the structure 114. However, when all the side surfaces of the structure 114 have convex shapes, the structure 114 can become large. To prevent this, a convex shape can be provided on at least one of a plurality of side surfaces of the structure 114 in accordance with the size or the like requested of an apparatus including the structure 114.

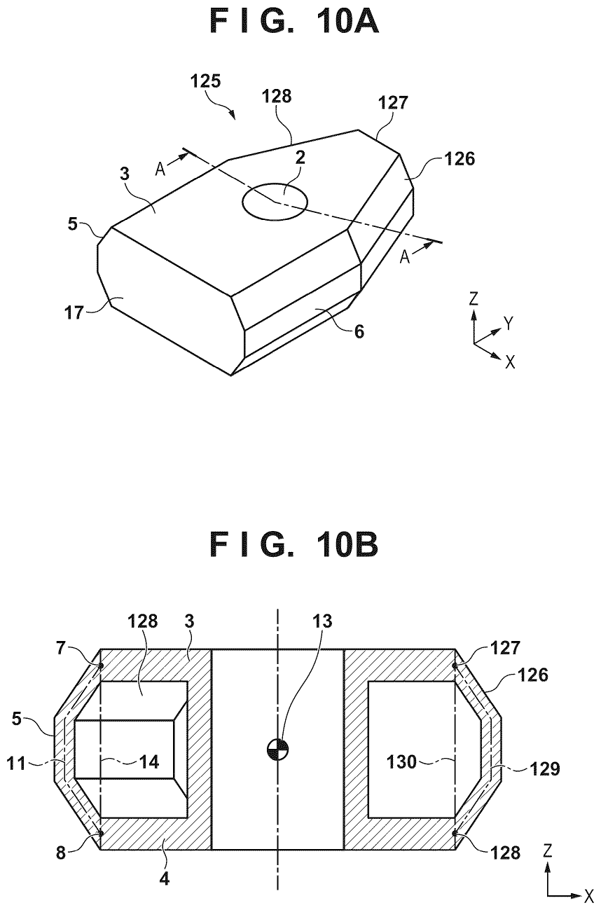

The 10th embodiment will be explained below. Matters which will not be mentioned as the 10th embodiment may or may not be pursuant to at least one of the first to ninth embodiments. FIGS. 10A and 10B are schematic views showing a structure 125 according to the 10th embodiment. FIG. 10A is an oblique view from above, and FIG. 10B is a sectional view taken along a line A-A in FIG. 10A.

The structure 125 can include connecting portions 5, 6, 17, 126, and 128 that connect a first plate 3 and a second plate 4. The connecting portions 6 and 126 can form an internal angle of larger than 90° when viewed from the top (orthogonal projection to the X-Y plane). The connecting portions 5 and 128 can form an internal angle of larger than 90° when viewed from the top. The connecting portion 126 and a connecting portion 127 can form an internal angle of larger than 90° when viewed from the top (orthogonal projection to the X-Y plane). The connecting portions 128 and 127 can form an internal angle of larger than 90° when viewed from the top (orthogonal projection to the X-Y plane).

The connecting portions 5, 6, 126, and 127 can have convex shapes in directions away from a barycenter 13 of the structure 125. A center line 129 as an aggregate of center points of the connecting portion 126 in the direction of thickness may be spaced more apart from the barycenter 13 of the structure 125 than a virtual line 130 connecting a center 127 of the boundary between the connecting portion 126 and the first plate 3 and a center 128 of the boundary between the connecting portion 126 and the second plate 4. The connecting portion 128 can also have a configuration similar to that of the connecting portion 126.

In an apparatus in which the structure 125 is built in, various constituent components can be arranged around the structure 125. Thus, the structure 125 having a shape other than a rectangular shape when viewed from the top can improve the space use efficiency. In the structure 125, the first plate 3 and the second plate 4 can take arbitrary shapes. The connecting portion that connects the first plate 3 and the second plate 4 can take a convex shape in the direction away from the barycenter 13 regardless of the shapes of the first plate 3 and second plate 4, thereby increasing the eigenfrequency. The shapes of the first plate 3 and second plate 4 need not always include linear portions, and may be, for example, circular. Even with the circular shapes, the connecting portion that connects the first plate 3 and the second plate 4 can take a convex shape in the direction away from the barycenter 13, which can increase the eigenfrequency. The shapes and arrangement of the first plate 3, second plate 4, and connecting portions can be determined in accordance with specifications required.

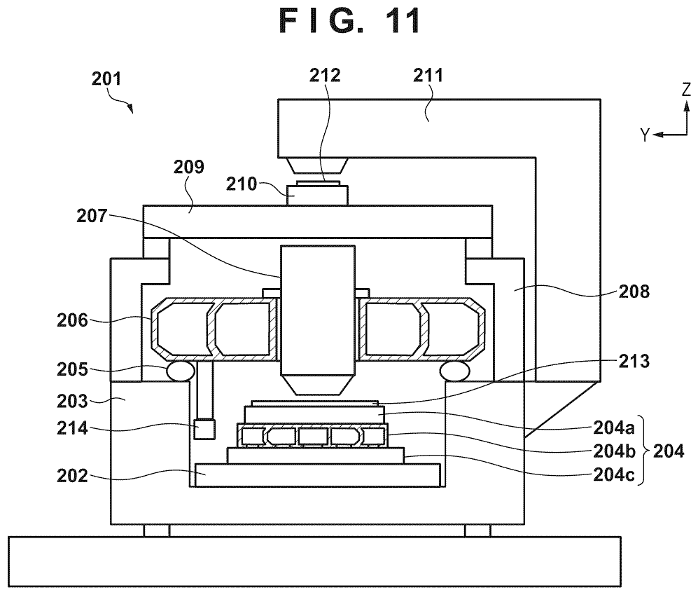

The 11th embodiment will be explained below. FIG. 11 schematically shows the configuration of an exposure apparatus 201 according to the 11th embodiment. The structures exemplified as the first to 10th embodiments can be built in the exposure apparatus 201. The exposure apparatus 201 aligns an original (reticle) 212 and a substrate 213, and projects the pattern of the original 212 to the substrate 213 via a projection optical system 207, thereby exposing the substrate 213. The exposure apparatus 201 includes an illumination optical system 211 that illuminates the original 212 with a light beam, and an original stage mechanism 210 that drives the original 212. The exposure apparatus 201 also includes a projection optical system 207 that projects the pattern of the original 212 to the substrate 213, and a substrate stage mechanism 204 that drives the substrate 213.

The projection optical system 207 is supported by a lens barrel surface plate 206. Here, the configuration of the above-described structure is applicable to the lens barrel surface plate 206. The lens barrel surface plate 206 can include the first plate, the second plate, and connecting portions having convex shapes in directions away from the barycenter of the lens barrel surface plate 206. This can increase the eigenfrequency while suppressing an increase in the weight of the lens barrel surface plate 206. In the example shown in FIG. 11, the lens barrel surface plate 206 includes connecting portions arranged in two lines. The lens barrel surface plate 206 can be supported by a base frame 203 via a mount 205. A pneumatic actuator is built in the mount 205, and the position of the lens barrel surface plate 206 can be actively controlled. Note that another actuator such as a linear motor may be used instead of the pneumatic actuator, or a plurality of types of actuators may be used.

The substrate stage mechanism 204 includes a substrate chuck 204a that holds the substrate 213, a top plate 204b that supports the substrate chuck 204a, and a driving unit 204c that drives the top plate 204b. Here, the configuration of the above-described structure is applicable to the top plate 204b. The top plate 204b can include the first plate, the second plate, and connecting portions having convex shapes in directions away from the barycenter of the top plate 204b. This can increase the eigenfrequency while suppressing an increase in the weight of the top plate 204b.

The position of the top plate 204b (substrate stage) of the substrate stage mechanism 204 can be measured by a laser interferometer 214. The top plate 204b is controlled based on an output from the laser interferometer 214. The substrate stage mechanism 204 is supported by a substrate stage surface plate 202, and the substrate stage surface plate 202 can be supported by the base frame 203.

The original stage mechanism 210 is supported by an original stage surface plate 209, and the original stage surface plate 209 is supported by an original stage frame 208 supported by the base frame 203. The position of the original stage of the original stage mechanism 210 is measured by a laser interferometer (not shown), and controlled based on an output from the laser interferometer.

In the exposure apparatus 201, the substrate 213 is loaded onto the substrate chuck 204a of the substrate stage mechanism 204 by a conveyance mechanism (not shown). The substrate 213 loaded on the substrate chuck 204a undergoes measurement for alignment by an alignment sensor (not shown), and then undergoes exposure processing. More specifically, the position of a mark formed on the substrate 213 by a previous process is detected by the alignment sensor, and exposure processing is performed based on the result while controlling the top plate 204b of the substrate stage mechanism 204. Hence, a pattern can be accurately superimposed on the substrate 213.

In the exposure apparatus 201 according to this embodiment, the eigenfrequency can be increased while suppressing an increase in the weights of the lens barrel surface plate 206 and top plate 204b, so exposure processing can be performed at high accuracy. Various mounting targets such as the projection optical system and the laser interferometer can be mounted on the lens barrel surface plate 206. As the performance of the exposure apparatus 201, the eigenfrequency is preferably considered in an assembly state in which these mounting targets are mounted. Therefore, when various mounting targets are attached to the lens barrel surface plate 206, connecting portions preferably have convex shapes in directions away from the barycenter of the lens barrel surface plate assembly on which the mounting targets are mounted. This also applies to the top plate, and connecting portions preferably have convex shapes in directions away from the barycenter of the top plate assembly on which mounting targets are mounted.

An article manufacturing method of manufacturing an article using the exposure apparatus 201 will be explained below. The article manufacturing method can include an exposure step of exposing a substrate using the exposure apparatus 201, and a processing step of processing the substrate having undergone the exposure step, thereby obtaining an article.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-227963, filed Dec. 24, 2024, which is hereby incorporated by reference herein in its entirety.

What is claimed is:

1. A structure comprising: a first plate; a second plate arranged to face the first plate; and a first connecting portion and a second connecting portion that connect the first plate and the second plate,
wherein the first plate includes a surface forming an upper surface of the structure,
the second plate includes a surface forming a lower surface of the structure, and
on a section orthogonal to the upper surface and the lower surface, the first connecting portion and the second connecting portion have convex shapes in directions away from a barycenter of the structure.

2. The structure according to claim 1, wherein on a section passing through the barycenter of the structure and orthogonal to the upper surface and the lower surface, the first connecting portion and the second connecting portion have convex shapes in the directions away from the barycenter of the structure.

3. The structure according to claim 1, wherein the upper surface and the lower surface are parallel to a horizontal surface, and
on a section passing through the barycenter of the structure and orthogonal to the upper surface and the lower surface, the first connecting portion and the second connecting portion have convex shapes from the barycenter in a horizontal direction.

4. The structure according to claim 3, wherein the structure has a through hole passing through the first plate and the second plate, and
the barycenter is positioned in the through hole.

5. The structure according to claim 1, wherein the first connecting portion includes a surface forming a first side surface of the structure, and
the second connecting portion includes a surface forming a second side surface of the structure.

6. The structure according to claim 5, wherein on the section orthogonal to the upper surface and the lower surface, the first side surface and the second side surface have convex shapes in the directions away from the barycenter of the structure.

7. The structure according to claim 6, wherein each of the first side surface and the second side surface has a ridge line and a flat surface.

8. The structure according to claim 6, wherein each of the first side surface and the second side surface has two ridge lines and three flat surfaces.

9. The structure according to claim 6, wherein each of the first side surface and the second side surface has a curved surface.

10. The structure according to claim 9, wherein a generating line of the curved surface is parallel to the upper surface and the lower surface.

11. The structure according to claim 1, wherein the first plate has a first through hole and the second plate has a second through hole,
the structure includes a cylindrical portion that connects the first plate and the second plate, and
an inner surface of the cylindrical portion, the first through hole, and the second through hole form one cylindrical surface.

12. The structure according to claim 1, wherein the first connecting portion is arranged to provide, in the structure, a first internal space partially defined by the first plate, the second plate, and the first connecting portion, and
the second connecting portion is arranged to provide, in the structure, a second internal space partially defined by the first plate, the second plate, and the second connecting portion.

13. The structure according to claim 1, wherein a hole is provided in at least one of the first connecting portion and the second connecting portion.

14. The structure according to claim 1, further comprising a third connecting portion and a fourth connecting portion that connect the first plate and the second plate,
wherein the third connecting portion is arranged between the first connecting portion and the barycenter of the structure, and
the fourth connecting portion is arranged between the second connecting portion and the barycenter.

15. The structure according to claim 14, wherein on the section, the third connecting portion and the fourth connecting portion have convex shapes in the directions away from the barycenter of the structure.

16. The structure according to claim 14, wherein the first plate has a first through hole and the second plate has a second through hole,
the structure includes a cylindrical portion that connects the first plate and the second plate,
an inner surface of the cylindrical portion, the first through hole, and the second through hole form one cylindrical surface, and
the cylindrical portion is arranged between the third connecting portion and the fourth connecting portion.

17. An exposure apparatus that exposes a substrate, comprising:
a projection optical system configured to project a pattern of an original to the substrate;
a substrate chuck configured to hold the substrate; and
a structure formed to support one of the projection optical system and the substrate chuck,
wherein the structure comprises: a first plate; a second plate arranged to face the first plate; and a first connecting portion and a second connecting portion that connect the first plate and the second plate,
wherein the first plate includes a surface forming an upper surface of the structure,
the second plate includes a surface forming a lower surface of the structure, and
on a section orthogonal to the upper surface and the lower surface, the first connecting portion and the second connecting portion have convex shapes in directions away from a barycenter of the structure.

18. An article manufacturing method comprising:
exposing a substrate using an exposure apparatus defined in claim 17; and
processing the substrate having undergone the exposing, thereby obtaining an article.
